(19) United States
(12) Patent Application Publication
(10) Pub. No.: US 2013/0342974 A1
(43) Pub. Date: Dec. 26, 2013

(54) HINGE STRUCTURE AND PORTABLE DEVICE USING THE SAME

(71) Applicant: ANT PRECISION INDUSTRY CO., LTD, Taipei (TW)

(72) Inventors: Pei-Chiao Hung, Taipei (TW); Stefan Voit, Taipei (TW)

(73) Assignee: ANT PRECISION INDUSTRY CO., LTD., Taipei (TW)

(21) Appl. No.: 13/656,610

(22) Filed: Oct. 19, 2012

(30) Foreign Application Priority Data
Jun. 25, 2012 (TW) 101122593

(51) Int. Cl. F16C 11/04; H05K 7/00

(52) U.S. Cl. 361/679.01; 16/387; 16/223

(57) ABSTRACT

A hinge structure of the present disclosure to be used with an electrical conductor is provided. The hinge structure comprises a first positioning member, a second positioning member, and at least one electrical conductor. One side of the first positioning member forms a plurality of first fixing portions, the other side has a shaft. The shaft has two openings and a tunnel connecting the two openings for the passage of the electrical conductor. The shaft further forms a slot for receiving the electrical conductor. One side of the second positioning member has a sleeve portion, and the other side has a plurality of second fixing portions. The sleeve portion is rotatively engaged with the shaft, such that the hinge structure of the present disclosure may be reduced its dimensions. Accordingly, the portable electronic device applying the hinge structure may be light-weighted and miniaturized.

### CROSS-REFERENCE TO RELATED APPLICATIONS

This application claims the benefit of Taiwan application Serial No. 101122593, filed on Jun. 25, 2012, the entire contents of which are hereby incorporated by reference.

### TECHNICAL FIELD

The present disclosure relates generally to a hinge structure, and more specifically to a portable electronic device and the hinge structure thereof having a hollow shaft allowing the passage of electrical conductors.

### BACKGROUND OF THE INVENTION

Hinges are generally configured to couple two objects so as to allow a pivotal rotation of certain angles with respect to each other. Therefore, hinges are often applied in portable electronic devices having a base component and a lid component. Examples of such electronic devices include, but are not limited to, a laptop computer, a mobile phone, an electronic dictionary or any clamshell type electronic device. By movably coupling the base component and the lid component with the hinge, the hinge allows the lid component to rotate or pivot relative to the base component. Accordingly, the lid component may be movable about the hinge between a closed position against the base component and an open position with a display of the lid component exposed for use.

Conventionally, electrical conductors, such as electrical wires or cables, are connected from the motherboard of the base component to the display of the lid component through the hinge structure and such electrical conductors may be obstructed or even snagged between the hinge structure. To avoid such situation, sizes of the electrical conductors need to be reduced. However, the reduced-sized electrical conductors may complicate the design and deployment of the wirings of the portable electronic device and consequently raise the difficulties in their downsizing and weight reducing. That is, when the sizes of the components of a portable electronic device are reduced, wirings between the base component and the lid component become complicated since there's less leeway for extra electrical conductors or inappropriate design. For example, the electrical conductors may be tangled with the hinge which may cause damage to the electrical conductors or prevent the hinge structure from pivoting smoothly.

According to a prior art reference, U.S. Pub. 2011/0242756, titled “COMPUTER HINGE HAVING A HOLLOW CLUTCH,” a design for electrical conductors to pass through hinge assemblies is provided. Referring to FIG. 1, the hollow shaft 10 includes a fastening component 20, a clutch component 30, a friction component 40 and a pivot mount 48. The clutch component 30 integrally forms a fastening base 24 having multiple fastening holes 22 to provide a better hardness for the fastening component 20. The friction component 40 is movably connected about the clutch component 30 to form the pivot mount 48 having multiple fastening holes 46. The pivot mount 48 extends to one side of the friction component 40 to be fixed with a lid component of an electronic device (not illustrated.) In addition, the fastening base 24 is to be fixed with the body of the electronic device (not illustrated.) The clutch component 30 has a pivot cavity 32 for one or more electrical conductors (not illustrated) to pass through.

According to the aforementioned prior art reference, during the manufacturing process of the electronic device, the electrical conductors need to be passed through the hollow shaft 10 before the electrical conductors can be welded with a connector (not illustrated.) However, a hinge structure having electrical conductors passed through may cause inconvenience to the connector welding process. Manufacturing cost may also be raised due to the elevated inconvenience of welding automation and increased processing time. Such situation may even be worsened due to the assembling difficulties caused by conventional hinges and electrical conductors being designed by different manufacturers and not being customized to alleviate assembling inconvenience. Therefore, the present disclosure provides a hinge structure to improve the cost and efficiency of downsizing and weight reducing of portable electronic devices.

### SUMMARY OF THE INVENTION

In one embodiment, a hinge structure to be assembled with electrical conductors is provided. The hinge structure includes a first positioning member, a second positioning member and at least one electrical conductor. Multiple first fixing portions are formed at one end of the first positioning member, whereas a shaft is formed at another end of the first positioning member. The multiple first fixing portions may be formed at a positioning board of the first positioning member, and the positioning board may be separable from the shaft. The shaft may further have a cover, which may or may not be removable from the shaft. In addition, the shaft includes two openings and a tunnel connecting the two openings for the electrical conductor to pass from one opening to the other. A sleeve portion is formed at one end of the second positioning member, whereas multiple second fixing portions are formed at another end. The sleeve portion is to be fixed to the lid component and is adapted to house the shaft so the lid component may pivot with respect to the shaft.

In another embodiment, the shaft further includes a slot connecting the two openings for receiving the electrical conductor. The slot may be covered by the cover. When the slot is covered by the cover, the cover and the shaft may be secured together by welding, gluing, screwing or any other suitable measures, as will be readily appreciated by those skilled in the art. The cover may be of any suitable length as long as the electrical conductor may be secured within the shaft. That is, the cover may be longer than, shorter than or equal to the length of the slot. In addition, the internal diameter of the sleeve portion is larger than the internal diameter of the shaft. The sleeve portion further includes a shaft slot between the sleeve portion and the second positioning member. The hardness of the second positioning member or the sleeve portion may be larger or smaller than the hardness of the shaft or the cover. As a result, a certain amount of friction is provided between the sleeve portion and the shaft during component rotation.

The present disclosure further provides a portable electronic device having a base component, a lid component and the hinge structure disclosed herein coupling the base and lid components. The base component is fixed with the first positioning member and the lid component is fixed with the second positioning member so as to enable the base component and the lid component to be moved or pivoted with respect to each other about the hinge structure. Details of the hinge structure have been disclosed in the previous paragraphs and therefore will not be repeated.

Accordingly, in one example, a hinge structure and the accompanying portable electronic device allowing electrical conductors to pass through its hollow shaft are provided. In another example, a hinge structure and the accompanying portable electronic device configured to provide manufacturing and/or assembling convenience are provided. In yet another example, a hinge structure and the accompanying portable electronic device for reducing processing time and/or manufacturing cost for downsized and/or weight-reduced electronic devices are provided.

It should be understood, however, that this Summary may not contain all aspects and embodiments of the present disclosure, that this Summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a hinge structure disclosed of the prior art reference: U.S. Pub. 2011/0242756, titled “COMPUTER HINGE HAVING A HOLLOW CLUTCH;”

FIGS. 2A-2E are side-views of the hinge structure having a shaft and a cover according to some embodiments of the present disclosure;

FIGS. 3A and 3B are side-views of the hinge structure having a slide-in cover according to some embodiments of the present disclosure; FIGS. 3C-3E are side cross-sectional views of the hinge structure having a cover;

FIGS. 4A and 4B are side-views of the hinge structure having a flip cover according to some embodiments of the present disclosure; FIG. 4C is a cross-sectional view of the hinge structure having a flip cover;

FIGS. 5A-5C are side cross-sectional views of a part of the hinge structure having no cover according to some embodiments of the present disclosure; and

FIG. 6 is a partial side view of the hinge structure being installed with a portable electronic device according to some embodiments of the present disclosure.

In accordance with common practice, the various described features are not drawn to scale and are drawn to emphasize features relevant to the present disclosure. Like reference characters denote like elements throughout the figures and text.

### DETAILED DESCRIPTION OF THE INVENTION

The present disclosure will now be described more fully hereinafter with reference to the accompanying drawings, in which exemplary embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

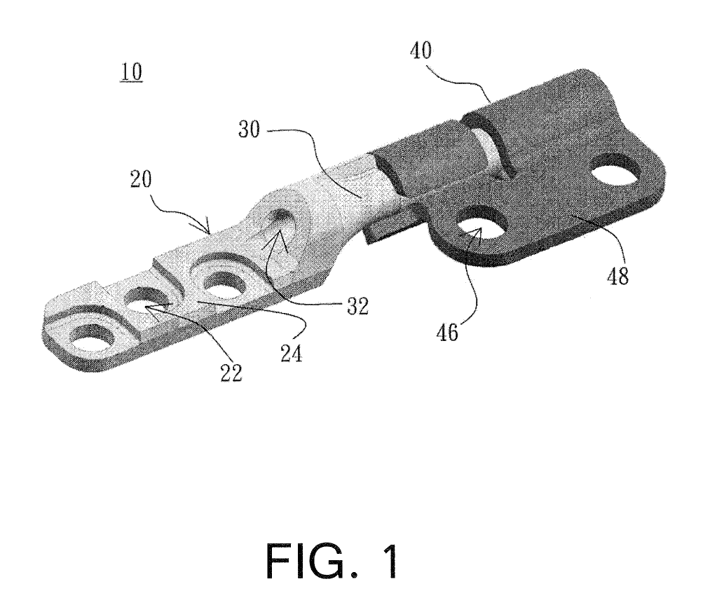

The description will be made as to the embodiments of the present disclosure in conjunction with the accompanying drawings in FIGS. 1-6. Reference will be made to the drawing figures to describe the present disclosure in detail, wherein depicted elements are not necessarily shown to scale and wherein like or similar elements are designated by same or similar reference numeral through the several views and same or similar terminology. In accordance with the purposes of this disclosure, as embodied and broadly described herein, this disclosure,

The present disclosure discloses a hinge structure and the accompanying portable electronic device for an electrical conductor to be assembled with a hinge more conveniently. While the portable electronic device here may be a portable computer, it may include, but is not limited to, a mobile phone, an electronic dictionary or any clamshell type electronic device. In addition, the electrical conductor to be assembled with the hinge structure preferably may include, but is not limited to electrical wires, teflon cables or silver wires. However, in different embodiments, the electrical conductor may be a coaxial cable or any other suitable cables or wires, as will be readily appreciated.

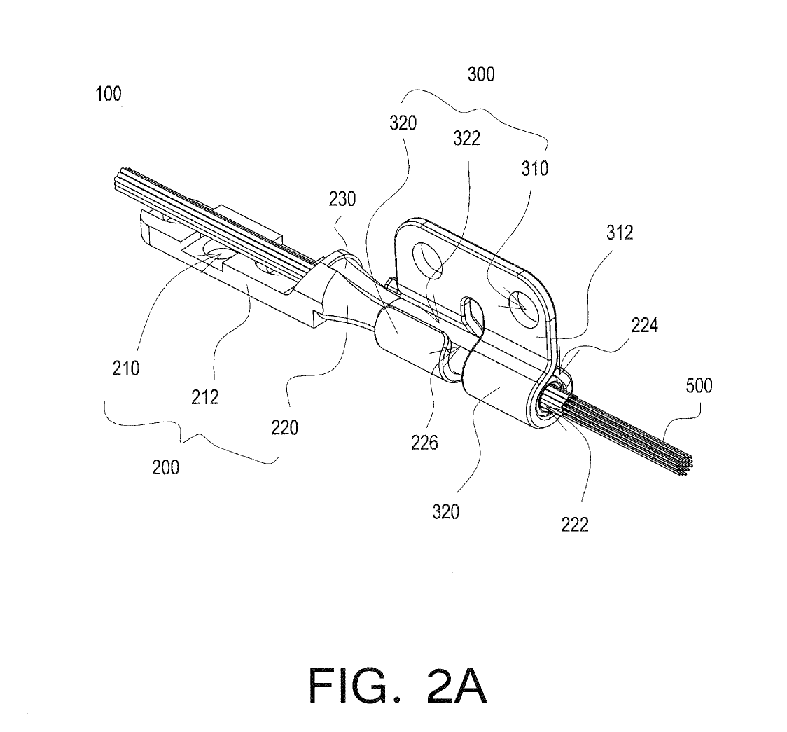

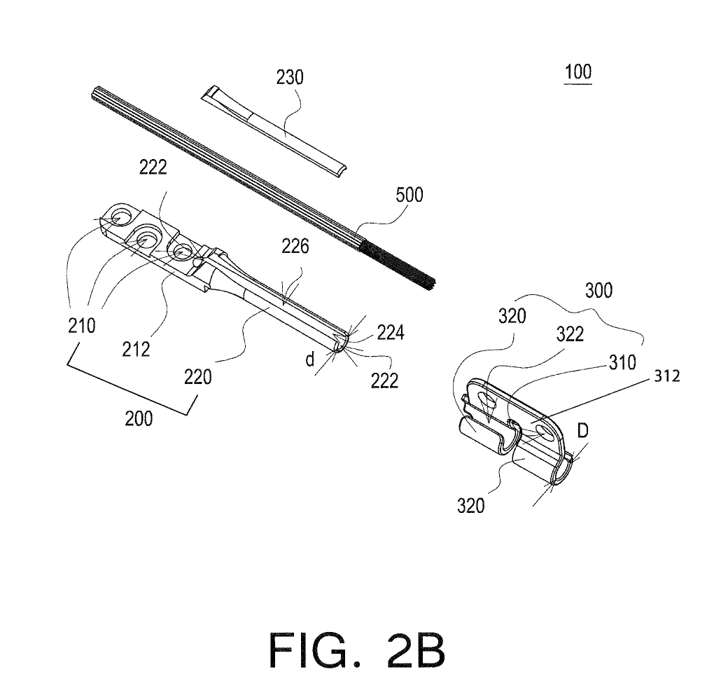

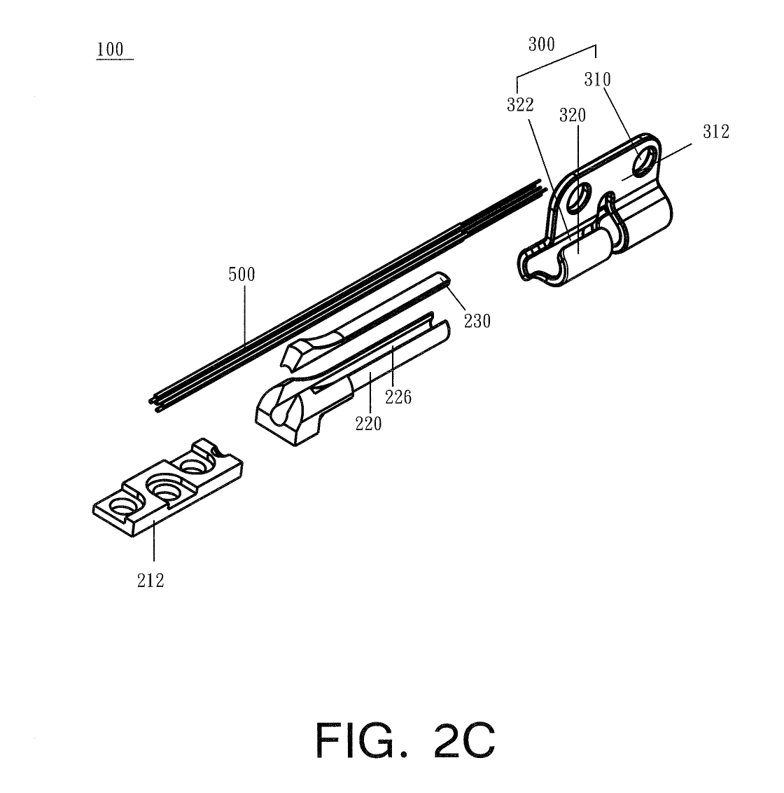

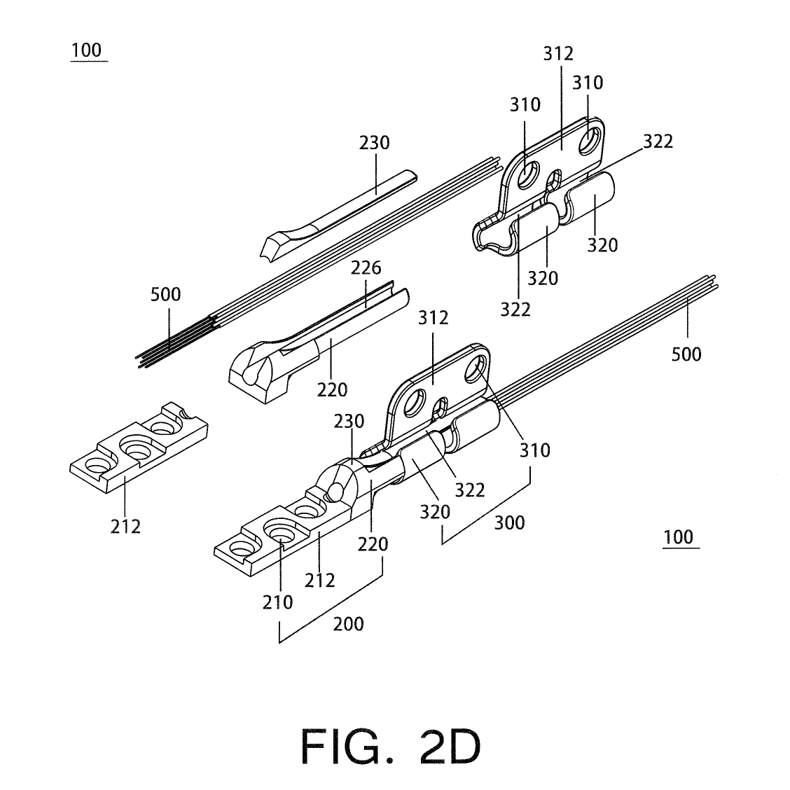

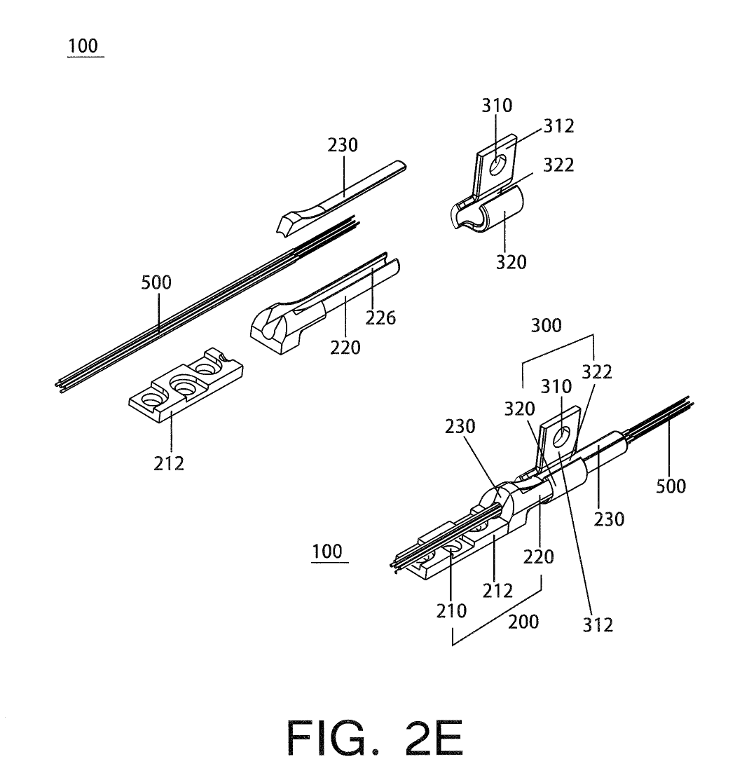

FIGS. 2A-2E are side-views of the hinge structure having a shaft and a cover according to some embodiments of the present disclosure.

Referring to FIGS. 2A and 2B, the hinge structure 100 of the present disclosure includes a first positioning member 200, a second positioning member 300 and at least one electrical conductor 500. The electrical conductor 500 may include one or more cables, wires or other electrical connectors (not illustrated), or a collection of cables, wires or other electrical connectors (not illustrated) which may be enclosed in an outer cover or otherwise bounded together, as will be readily appreciated. Such electrical conductor 500 generally serves to transport the power and to establish communications between devices in the lid component and the base component of a portable electronic device (not illustrated), such as power and/or data from the based component to a display device in the lid component.

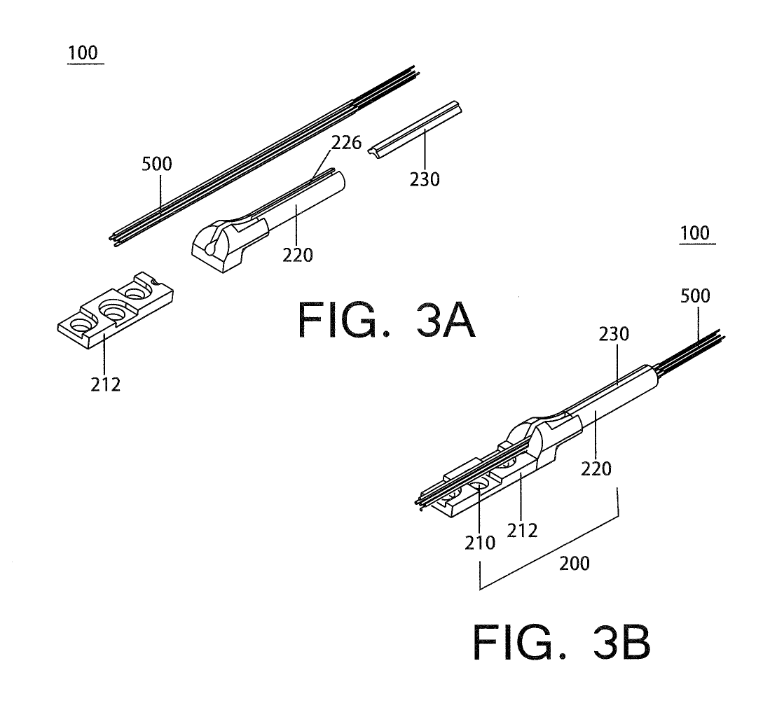

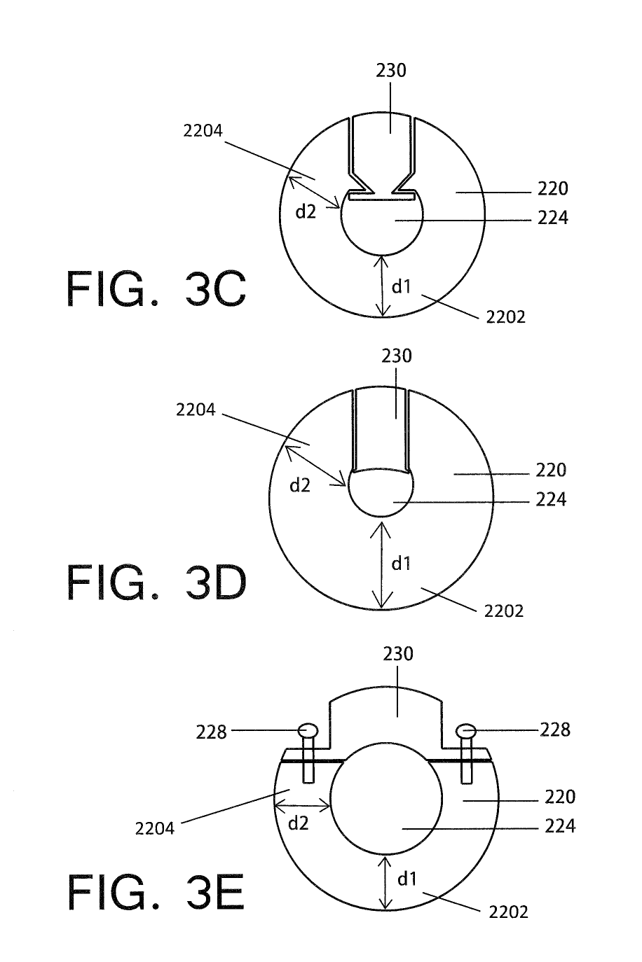

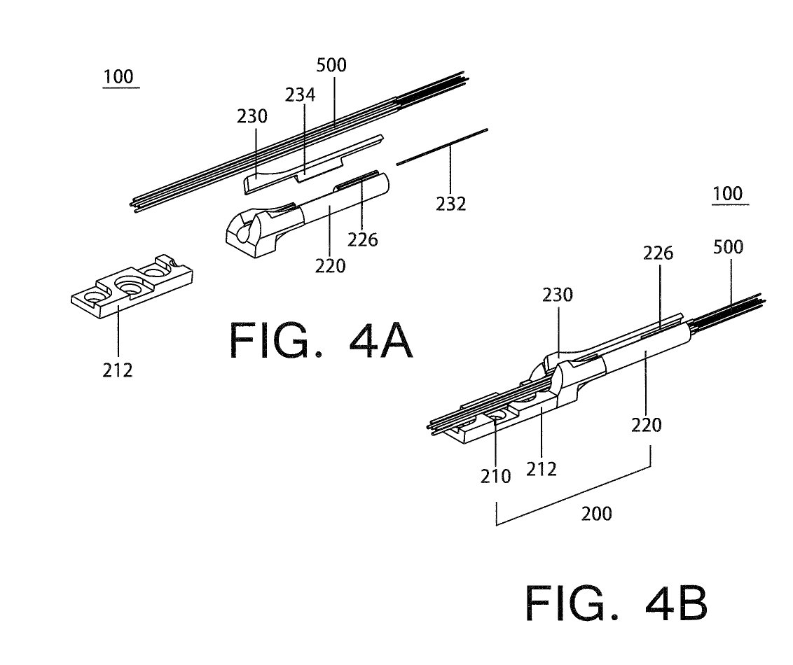

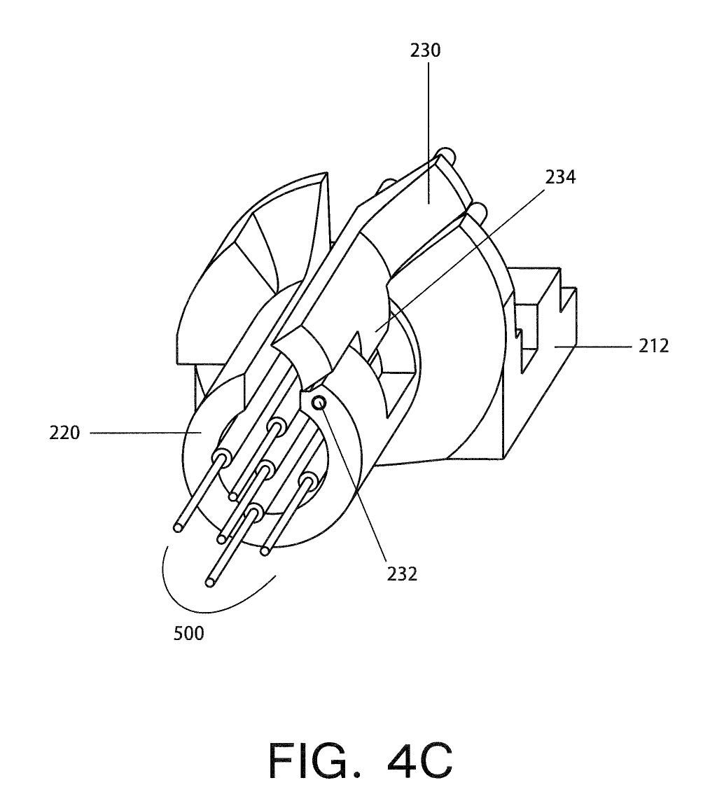

As shown, multiple first fixing portions 210 may be formed at one end of the first positioning member 200, whereas a shaft 220 and a cover 230 may be configured at another end of the first positioning member 200. In this embodiment, the first fixing portions 210 may be apertures suitable for receiving fasteners such screws, bolts, nails, pins, rivets or any other suitable fastening devices, as will be readily appreciated by those skilled in the art. In addition, the first fixing portions 210 are formed at a positioning board 212 connected to one end of the shaft 220. It is to be noted that while FIGS. 2A and 2B illustrates that the positioning board 212 and the shaft 220 are connected, the positioning board 212 and the shaft 220 may not be formed integrally. That is, the positioning board 212 may be separable from the shaft 220. Referring to FIG. 2C, the positioning board 212 and the shaft 220 may be separate components, and the positioning board 212 may be fixed to the shaft 220 by means of electric welding, supersonic welding, clamping or any suitable joining technique readily perceivable by person having ordinary skill in the art. In addition, the shaft 220 may have two openings 222 and a tunnel 224 connecting the two openings 222 for the passage of the electrical conductor 500. The shaft 220 may further include a slot 226 connecting the two openings 222 for cooperating with a cover 230. The slot 226 may also serve to facilitate the electrical conductor 500 within the hinge structure 100 without the necessity of passing the electrical conductor 500 through the tunnel 224 from one opening to the other. That is, the slot 226 may provide convenience for the assembly of the electrical conductor 500 and the hinge structure 100. After the electrical conductor 500 is received by the tunnel 224 through the slot 226, the slot 226 may be covered by the cover 230 so the electrical conductor 500 may be secured within the shaft 220. The secured electrical conductor 500 within the shaft 220 helps to reduce electrical conductor sliding and reduces the probability of electrical conductor snagging. In this way, the reduced snagging provides for long term reliability. It should be understood that when the slot 226 is covered by the cover 230, the cover 230 may be fixed to the shaft 220 by welding, gluing, screwing or any suitable engagement means. Additional exemplary engagement means of the cover 230 and the shaft 220 will be further described in the following embodiments in FIGS. 3A-3E and 4A-4C. In addition, the length of the cover 230 may be similar to that of the slot 226. In other embodiments, the length of the cover 230 may be longer or shorter than that of the slot 226, as long as the electrical conductor 500 may be secured within the shaft 220.

Moreover, the second positioning member 300 may have a sleeve portion 320 at one end and multiple second fixing portions 310 at the other end. As illustrated in FIGS. 2A and 2B, a pair of sleeve portions 320 are provided and connected by a bearing plate 312. The structures of the second fixing portions 310 are similar to those of the first fixing portions 210. That is, the second fixing portions 310 may be apertures suitable for receiving fasteners such screws, bolts, nails, pins, rivets or any other suitable fastening devices, as will be readily appreciated by those skilled in the art. The sleeve portion 320 may be fixed to the lid component (not illustrated) and adapted to house the shaft 220 so the lid component may pivot with respect to the shaft 220. In addition, the sleeve portion 320 may be served to provide friction against the shaft 220 during component rotation. As shown, sleeve slots 322 may further be formed at the sleeve portion 320 between the sleeve portions 320 and the second positioning member 300, i.e., the bearing plate 312. In one embodiment, the sleeve portion 320 and the bearing plate 312 may be integrally formed as a single part and be made of SK7, tool steel or other suitable materials, as will be readily appreciated.

It is to be noted that the number and the configuration of the sleeve portion(s) 320 and the corresponding sleeve slot(s) 322 may be varied. For example, in FIGS. 2B and 2C, the second positioning member 300 may have two sleeve portions 320, and their corresponding sleeve slots 322 may have openings on opposite sides of the bearing plate 312. In another example, as illustrated in FIG. 2D, the second positioning member 300 may have two sleeve portions 320, and their corresponding sleeve slots 322 may have openings on a same side of the bearing plate 312. In yet another example, as illustrated in FIG. 2E, the second positioning member 300 may have only one sleeve portion 320. In sum, the second positioning member 300 may have any number and configuration of sleeve portion(s) 320 and the corresponding sleeve slot(s) 322 for manufacturing easiness, cost reduction, strength of the hinge structure 100 or any suitable reason readily perceivable by person having ordinary skill in the art.

Accordingly, In the present disclosure, when assembling the hinge structure 100 and an electrical conductor 500 having a connector (not illustrated), the electrical conductor 500 may pass through the slot 226 into the shaft 220. That is, the electrical conductor 500 may be pre-welded with the connector and still capable of being assembled with the hinge structure 100 easily. Thereafter, after covering the slot 226 with the cover 230 and securing the cover 230 to the shaft 220 by suitable fastening means, a semi-finished product, i.e., the hinge structure 100, to be assembled with the base component and the lid component of a portable electronic device may be provided.

It should be noted that the cross-sectional shape of the shaft 220 may be substantially cylindrical, but the present disclosure is not so limited. Moreover, the friction between the sleeve portion 320 and the shaft 220 may be best maintained when the shaft 220 has a comparatively high hardness. In one embodiment, the materials of the cover 230 and the shaft 220 may be the same. The material may be a medium carbon free-cutting steel (S50C), an iron-nickel alloy injection molding, zinc alloy die casting molding or any other suitable material. However, in another embodiment, the material of the cover 230 may be different from that of the shaft 220 to provide different friction/torsion for the hinge structure 100. Different manufacturing methods of the slot 226 may also lead to a change of the material of the cover 230 for the similar purposes. In sum, the hardness of the sleeve portion 320 may be preferably lower than that of the shaft 220 or the cover 230. However, in other embodiments, the hardness of the sleeve portion 320 may be higher than that of the shaft 220 or the cover 230 so as to provide a desired friction/torsion for the hinge structure 100. It is to be noted that the shaft 220 may have grooves engraved on its exterior. The grooves may serve to be a reservoir for grease, oil or any other suitable lubricant, as it may be desirable to facilitate the lubrication of various frictionally contacting parts within the hinge structure 100. As an exemplary result, the wear to the shaft 220 caused by the pivoting of the hinge structure 100 may be reduced such that the durability of the shaft 220 may be improved.

Moreover, a constant or dynamic friction/torsion is to be maintained between the sleeve portion 320 and the shaft 220 during the process of pivoting so the lid component of the portable electronic device that the hinge structure 100 is applied to may be maintained in a position between the predetermined open and closed positions. Such constant or dynamic friction/torsion may be achieved by configuring the geometric characteristics of the sleeve portion 320 and/or the shaft 220. For example, before assembling, the internal diameter of the sleeve portion 320 may be larger than the external diameter of the shaft 220. In another example, before assembling, the internal diameter of the sleeve portion 320 may be smaller than the external diameter of the shaft 220. It is to be noted that the configurations for maintaining a constant or dynamic friction/torsion between the sleeve portion 320 and the shaft 220 are not so limited. That is, the amount of friction/torsion between the sleeve portion 320 and the shaft 220 may further be determined by configuring the size of the sleeve portion 320, the material of the sleeve portion 320, and the material of the component (such as the shaft 220) that the sleeve portion 320 contacts, or any other configuration that will be readily appreciated by those having ordinary skill in the art.

FIGS. 3A and 3B are side-views of the hinge structure having a slide-in cover according to some embodiments of the present disclosure. FIGS. 3C-3E are side cross-sectional views of the hinge structure having a cover.

Referring to FIGS. 3A and 3B, with reference to the aforementioned embodiments, the hinge structure 100 may have a cover 230 for covering the slot 226 after the electrical conductor 500 is received within the shaft 220. In some embodiments, the cover 230 may be fixed to the shaft 220 by welding, gluing, screwing or any suitable fastening means. Alternatively, one end of the cover may have at least one guiding part to guide the cover 230 to slide into the slot 226. For example, with reference to FIGS. 3C and 3D, one end of the cover may be substantially T-shaped so when the cover 230 is slid, i.e., inserted, into the tunnel 224, the cover 230 may be substantially secured to the shaft 220 so as to prevent the electrical conductor (not illustrated) from escaping the shaft 220. That is, the cover 230 may be a slide-in style cover having a substantially T-shaped guiding part. In one embodiment, the inner surface of the shaft 220 may further have at least one protruding assembly part to cooperate with the guiding part, as illustrated in FIG. 3C. Alternatively, the shaft 220 may not have a protruding assembly part to cooperate with the guiding part, as illustrated in FIG. 3D. After the cover 230 is slid into the shaft 220, the cover 230 may be further fixed to the shaft 220 by any suitable means of fixing, as will be readily appreciated. Alternatively, the cover 230 may not be a slide-in style cover, as illustrated in FIG. 3E. Here, after the electrical conductor (not illustrated) is placed within the tunnel 204, a cover 230 may be applied to prevent the electrical conductor from escaping the shaft 220. In addition, fastener(s) 228 may be applied to secure the cover 230 to a sidewall of the shaft 220. Example of the fastener(s) 228 may include, but is not limited to, a screw, a pin, a bolt, a nail or a rivet. It is to be noted that the tunnel 224 may be off-centered with respect to the center of the shaft 220, as illustrated in FIG. 3D. Specifically, the center of the tunnel 224 may be closer to the slot 226 than the center of the shaft 220. In other words, the thickness d1, which is measured at a first position 2202 of the shaft 220, may be larger than the thickness d2, which is measured at a second position 2204 of the shaft 220. In this embodiment, the first position 2202 may be substantially opposite to the slot 226, and the second position 2204 may be closer to the slot 226 than the first position 2202. Such configuration may enhance the stiffness of the shaft 220 so as to improve the durability of the shaft 220. Such configuration may also serve to provide a dynamic friction between the shaft 220 and the sleeve portion 320 when pivoted with respect to each other. It should be understood that the off-centered design may be applicable to any hinge structure 100 having the cover 230 as disclosed in the present disclosure. That is, while the thicknesses d1 and d2 are substantially the same as illustrated in FIGS. 3C and 3E, in other embodiments, the thickness d1 may be larger than the thickness d2.

FIGS. 4A and 4B are side-views of the hinge structure having a flip cover according to some embodiments of the present disclosure. FIG. 4C is a cross-sectional view of the hinge structure having a flip cover.

Referring to FIGS. 4A and 4B, with reference to the aforementioned embodiments, the hinge structure 100 may have a cover 230 for covering the slot 226 after the electrical conductor 500 is received within the shaft 220. Here, the cover 230 may be rotatively engaged with the shaft 220. For example, the cover 230 may be assembled with the shaft 220 by means of a pin 232 so the cover 230 may be flipped open for the shaft 220 to receive the electrical conductor 500. Specifically, the cover 230 may have a bonding part 234 and the pin 232 may pass through the entire bonding part 234 to serve as a pivot. Alternatively, there may be two short pins (not illustrated) passing through two opposite ends of the bonding part 234 respectively, which may also enable the cover 230 to be flipped between an open position for receiving the electrical conductor 500 and a closed position for covering the slot 226. The manufacturing and/or assembly processes of the shaft 220 and/or the cover 230 may be simplified by the application of the two-pin configuration. After receiving the electrical conductor 500, the cover 230 may be flipped to cover the slot 226 (not illustrated) so as to prevent the electrical conductor from escaping the shaft 220. FIG. 4C is a cross-sectional view of a part of the hinge structure 100 having a flip cover 230. As illustrated, the cover 230 is connected to the shaft 220 by a pin 232 passing through the bonding part 234 so the cover 230 may pivot about the pin 232.

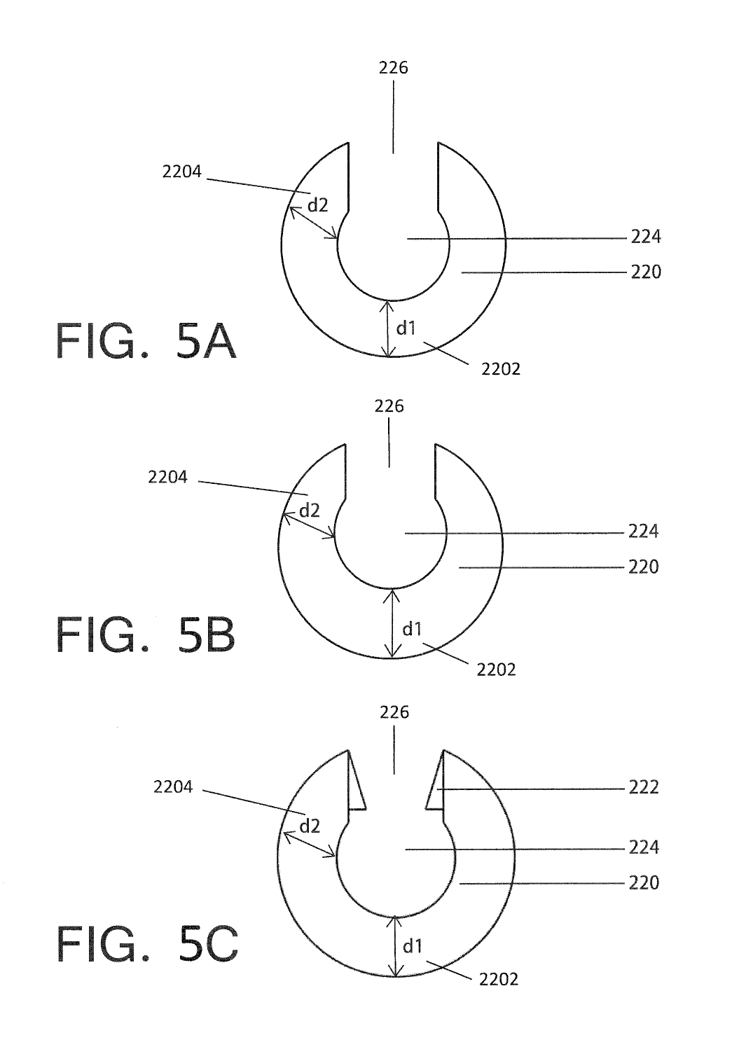

FIGS. 5A-5C are cross-sectional views of a part of the hinge structure having no cover according to some embodiments of the present disclosure.

In FIG. 5A, the shaft 220 and the tunnel 224 are provided. Here, as disclosed in the aforementioned embodiments, the tunnel 224 is configured to receive an electrical conductor (not illustrated.) However, unlike the embodiments disclosed in FIGS. 2A-4C, the shaft 220 does not have a cover 230 to prevent the electrical conductor from escaping the shaft 220. Specifically, before an electrical conductor is placed into the shaft 220, its radial dimension is to be reduced so it may be squeezed into the tunnel 224. Thereafter, the electrical conductor will substantially restore to its original dimension. Accordingly, the shaft 220 may form a close fit with the electrical conductor such that the electrical conductor may not easily escape the shaft 220. In one embodiment, the shaft 220 may have one or more baffles 222 to prevent the inserted electrical conductor from escaping. The one or more baffle(s) 222 may be made of any suitable flexible material so as to allow the electrical conductor to pass through without being damaged. It is to be noted that the tunnel 224 may be off-centered with respect to the center of the shaft 220. Specifically, the center of the tunnel 204 may be closer to the slot 226 than the center of the shaft 220. Referring to FIG. 5B, the thickness d1, which is measured at a first position 2202 of the shaft 220, may be larger than the thickness d2, which is measured at a second position 2204 of the shaft 220. In this embodiment, the first position 2202 may be substantially opposite to the slot 226, and the second position 2204 may be closer to the slot 226 than the first position 2202. Such configuration may enhance the stiffness of the shaft 220 so as to improve the durability of the shaft 220. Such configuration may also serve to provide a dynamic friction between the shaft 220 and the sleeve portion 320 when being pivoted with respect to each other. It should be understood that the off-centered design may be applicable to any hinge structure 100 not having a cover as disclosed in the present disclosure. That is, while the thicknesses d1 and d2 are substantially the same as illustrated in FIGS. 5A and 5C, in other embodiments, the thickness d1 may be larger than the thickness d2.

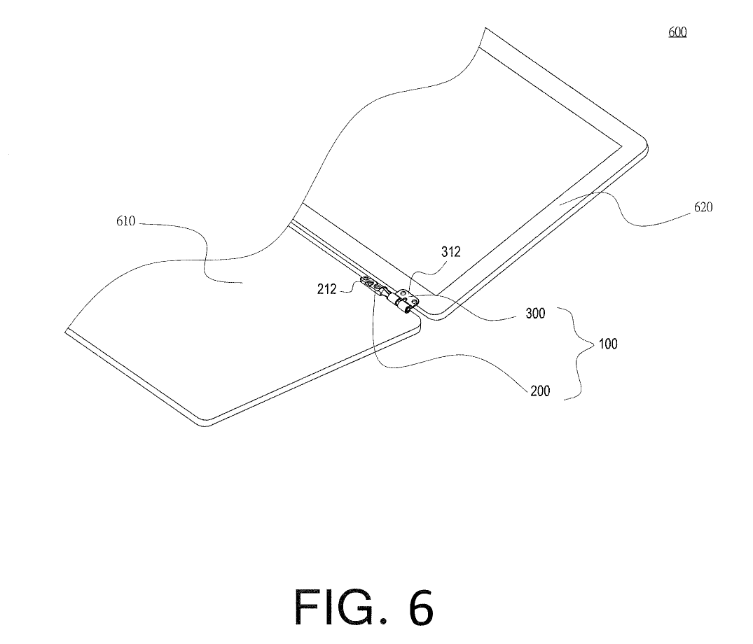

FIG. 6 is a partial side view of the hinge structure being installed with a portable electronic device according to some embodiments of the present disclosure.

Referring to FIG. 6, the present embodiment provides a portion of a portable electronic device 600 having a base component 610, a lid component 620 and the aforementioned hinge structure 100 for mechanically pivotally coupling the lid component 620 to the base component 610. Here, the portable electronic device 600 may be an Ultrabook or other light-weighted laptops. Alternatively, the portable electronic device 600 may be a mobile phone, an electronic dictionary or any clamshell type electronic device. The base component 610 may be fixed to the first positioning member 200 and the lid component 620 may be fixed to the second positioning member 300 such that the base component 610 and the lid component 620 may be moved or pivoted with respect to each other through the hinge structure 100. To be specific, the base component 610 is fixed to the positioning board 212 by fasteners (not illustrated) to be assembled with the hinge structure 100; and the lid component 620 is fixed with the bearing plate 312 by fasteners (not illustrated) to be assembled with the hinge structure 100. Details of the hinge structure 100 and the components thereof have been disclosed in the aforementioned embodiments and will not be repeated.

Lastly, it is to be noted that the sleeve portion 320 may be made of high carbon steel and the shaft 220 may be made of medium carbon steel to maintain the friction/torsion therebetween. Alternatively, the surfaces of the sleeve portion 320 and the shaft 220 may be treated with heat to provide different hardness so as to create different friction/torsion therebetween.

Previous descriptions are only embodiments of the present disclosure and are not intended to limit the scope of the present disclosure. Many variations and modifications according to the claims and specification of the disclosure are still within the scope of the claimed disclosure. In addition, each of the embodiments and claims does not have to achieve all the advantages or characteristics disclosed. Moreover, the abstract and the title only serve to facilitate searching patent documents and are not intended in any way to limit the scope of the claimed disclosure.

We claim:

1. A hinge structure comprising:
a first positioning member having a plurality of first fixing portions at one end of the first positioning member, and a shaft at another end of the first positioning member; and
a second positioning member having a sleeve portion at one end of the second positioning member, and a plurality of second fixing portions at another end of the second positioning member,
wherein the sleeve portion is rotatively engaged with the shaft, and the shaft forms a slot substantially along its longitudinal direction.

2. The hinge structure according to claim 1, wherein the shaft further including:
a first opening at one end of the shaft and a second opening at another end of the shaft; and
a tunnel connecting the first opening and the second opening, the tunnel penetrating the shaft,
wherein the slot connects the first opening and the second opening along the longitudinal direction of the shaft.

3. The hinge structure according to claim 1, wherein the first positioning member further including a positioning board that is separable from the shaft, wherein the first fixing portions are formed at the positioning board.

4. The hinge structure according to claim 1, wherein an internal diameter of the sleeve portion is larger than an internal diameter of the shaft.

5. The hinge structure according to claim 1, wherein the sleeve portion further includes a sleeve gap between the sleeve portion and the second positioning member.

6. The hinge structure according to claim 1, wherein the hardness of the second positioning member or the sleeve portion is higher than the hardness of the shaft.

7. The hinge structure according to claim 1, wherein the hardness of the second positioning member or the sleeve portion is lower than the hardness of the shaft.

8. The hinge structure according to claim 1, wherein the shaft including a first thickness and a second thickness, the first thickness of the shaft is larger than the second thickness of the shaft, wherein the first thickness is measured at a first position substantially opposite to the slot, and the second thickness is measured at a second position which is closer to the slot than the first position.

9. The hinge structure according to claim 2, wherein the tunnel is configured to be off-centered with respect to a center of the shaft.

10. A hinge structure comprising:
a first positioning member having a plurality of first fixing portions at one end of the first positioning member, and a shaft having a cover at another end of the first positioning member, the shaft further having a slot formed along its longitudinal direction; and
a second positioning member having a sleeve portion at one end of the second positioning member, and a plurality of second fixing portions at another end of the second positioning member,
wherein the cover is configured to cover the slot, and the sleeve portion is rotatively engaged with the shaft and the cover.

11. The hinge structure according to claim 10, wherein the shaft further including:
a first opening at one end of the shaft and a second opening at an opposite end of the shaft; and
a tunnel connecting the first opening and the second opening, the tunnel penetrating the shaft,
wherein the slot connects the first opening and the second opening along the longitudinal direction of the shaft.

12. The hinge structure according to claim 10, wherein the first positioning member further including a positioning board separable from the shaft, wherein the first fixing portions are formed at the positioning board.

13. The hinge structure according to claim 10, wherein one side of the cover has at least one guiding part to guide the cover to slide into the slot.

14. The hinge structure according to claim 10, further comprising a fastener configured to fix the cover to a sidewall of the shaft.

15. The hinge structure according to claim 10, wherein the cover is rotatively engaged with the slot by at least one pin such that the cover may be configured, with respect to the shaft, between a substantially open position for revealing the slot and a substantially closed position for covering the slot.

16. The hinge structure according to claim 10, wherein the shaft including a first thickness and a second thickness, the first thickness of the shaft is larger than the second thickness of the shaft, wherein the first thickness is measured at a first position substantially opposite to the slot, and the second thickness is measured at a second position which is closer to the slot than the first position.

17. The hinge structure according to claim 11, wherein the tunnel is configured to be off-centered with respect to a center of the shaft.

18. A portable electronic device, comprising:
a hinge structure, comprising
a first positioning member having a plurality of first fixing portions at one end of the first positioning member, and a shaft at another end of the first positioning member; and
a second positioning member having a sleeve portion at one end of the second positioning member, and a plurality of second fixing portions at another end of the second positioning member, wherein the sleeve portion is rotatively engaged with the shaft;
a lid component assembled with the first positioning member and a base component assembled with the second positioning member so as to enable the lid component to be pivoted with respect to the base component; and
an electrical conductor electronically connecting the base component to the lid component through the hinge structure.

19. The portable electronic device according to claim 18, wherein the shaft further includes a cover configured to cover the slot.

20. The portable electronic device according to claim 19, wherein the shaft further comprises:
a first opening at one end of the shaft and a second opening at an opposite end of the shaft;
a tunnel connecting the first opening and the second opening, the tunnel penetrating the shaft for the passage of the electrical conductor; and
a slot connecting the first opening and the second opening along the longitudinal direction of the shaft, the slot configured to accommodate the electrical conductor,
wherein the electrical conductor is disposed into the tunnel via the slot.
